(19) United States
(12) Patent Application Publication
(10) Pub. No.: US 2024/0222174 A1
(43) Pub. Date: Jul. 4, 2024

(54) SUBSTRATE TRANSFERRING APPARATUS, AND LIQUID PROCESSING APPARATUS AND SUBSTRATE PROCESSING EQUIPMENT INCLUDING SAME

(71) Applicant: SEMES CO., LTD., Cheonan-si (KR)

(72) Inventors: Seul Gi CHOI, Busan (KR); Jun Hyun LIM, Seoul (KR); Young Jin JANG, Cheonan-si (KR); Eun Jung LEE, Seoul (KR); Hee Jun YOUN, Goyang-si (KR); Gui Su PARK, Cheonan-si (KR)

(73) Assignee: SEMES CO., LTD., Cheonan-si (KR)

(21) Appl. No.: 18/395,570

(22) Filed: Dec. 24, 2023

(30) Foreign Application Priority Data
Dec. 29, 2022 (KR) 10-2022-0188681

(51) Int. Cl. H01L 21/677; H01L 21/67

(52) U.S. Cl. CPC H01L 21/67712; H01L 21/67057; H01L 21/67706

(57) ABSTRACT

Proposed is a substrate transferring apparatus, and a liquid processing apparatus and substrate processing equipment including the same, which prevent a pattern leaning phenomenon during a substrate processing process. The substrate transferring apparatus that transfers substrates between cleaning tanks in the batch-type liquid processing apparatus includes a rail extended on a ceiling of a first cleaning tank in which a first processing liquid is stored and a second cleaning tank in which a second processing liquid is stored, a crane moving along the rail, and a vessel configured to be moved vertically by the crane. The vessel may include a first sub vessel and a second sub vessel that combine with each other to form a space for accommodating a substrate immersed in the first processing liquid.

### CROSS REFERENCE TO RELATED APPLICATION

The present application claims priority to Korean Patent Application No. 10-2022-0188681, filed Dec. 29, 2023, the entire contents of which is herein incorporated by reference.

### BACKGROUND OF THE INVENTION

### Field of the Invention

The present disclosure relates to a substrate transferring apparatus, and a liquid processing apparatus and substrate processing equipment including the same.

### Description of the Related Art

The semiconductor manufacturing process is a process of manufacturing semiconductor devices on a substrate (e.g. wafer) and includes, for example, exposure, deposition, etching, ion implantation, cleaning, etc. In order to perform each manufacturing process, semiconductor manufacturing equipment for performing individual processes is provided in cleanrooms of a semiconductor manufacturing plant so that a processing process is performed on a substrate put into the semiconductor manufacturing equipment.

Various processing liquids and processing gases are used in each process, and particles and by-products are generated during the process. A cleaning process is performed before and after each process to remove these particles and process by-products from a substrate.

Equipment for the cleaning process is largely divided into a batch type in which multiple substrates are immersed in processing liquid and a single type in which processing liquid is supplied to one substrate. In the case of a batch type apparatus, first, substrates are immersed in a cleaning tank containing a cleaning solution to remove particles from the substrates through a chemical reaction, and then the substrates are secondarily immersed in a cleaning tank containing a rinsing solution to rinse the substrates.

Meanwhile, with the miniaturization in semiconductor manufacturing, the width between patterns formed on a substrate is very narrow, and a phenomenon in which patterns collapse due to surface tension (pattern leaning phenomenon) may occur as a substrate escapes from processing liquid.

### SUMMARY OF THE INVENTION

Accordingly, the present disclosure has been made keeping in mind the above problems occurring in the related art, and the present disclosure is intended to provide a substrate transferring apparatus, and a liquid processing apparatus and substrate processing equipment including the same, which prevent a pattern leaning phenomenon during a substrate processing process.

In order to achieve the above objective, according to an embodiment of the present disclosure, there is provided a substrate transferring apparatus that transfers substrates between cleaning tanks in a batch-type liquid processing apparatus, the substrate transferring apparatus, including: a rail extended on a ceiling of a first cleaning tank in which a first processing liquid is stored and a second cleaning tank in which a second processing liquid is stored; a crane moving along the rail; and a vessel configured to be moved vertically by the crane. The vessel may include a first sub vessel and a second sub vessel that combine with each other to form a space for accommodating a substrate immersed in the first processing liquid.

According to the present disclosure, the first sub vessel and the second sub vessel may have a barrel shape with a center cut out.

According to the present disclosure, the first sub vessel and the second sub vessel may be coupled to each other through horizontal movement.

According to the present disclosure, the crane may include: a movable body configured to move horizontally along the rail; a slide drive part having a first slide drive part and a second slide drive part, which are provided on the movable body and move closer to or farther away from each other; and a lifting belt having a first lifting belt and a second lifting belt respectively provided on the first slide drive part and the second slide drive part to raise or lower the first sub vessel and the second sub vessel.

According to the present disclosure, the vessel may be lowered into the first cleaning tank in a state of being separated into the first sub vessel and the second sub vessel so as to be located on opposite sides of the substrate, and as the first sub vessel and the second sub vessel are coupled to each other, the substrate immersed in the first processing liquid may be accommodated in the vessel.

According to the present disclosure, the vessel containing the substrate immersed in the first processing liquid may move to the second cleaning tank, and as the first sub vessel and the second sub vessel are separated from each other in the second cleaning tank, the substrate may be located in the second cleaning tank.

According to the present disclosure, the first processing liquid may be phosphoric acid (H3PO4), and the second processing liquid may be de-ionized water (DIW).

In order to achieve the above objective, according to an embodiment of the present disclosure, there is provided a batch-type liquid processing apparatus, including: a first cleaning tank configured to store a first processing liquid; a second cleaning tank configured to store a second processing liquid; and a substrate transferring apparatus configured to transfer a substrate to the first cleaning tank and the second cleaning tank. The substrate transferring apparatus may include: a transfer rail extended on a ceiling of the first cleaning tank in which the first processing liquid is stored and the second cleaning tank in which the second processing liquid is stored; a crane moving along the transfer rail; and a vessel configured to be moved vertically by the crane, wherein the vessel may include a first sub vessel and a second sub vessel that combine with each other to form a space for accommodating the substrate immersed in the first processing liquid.

In order to achieve the above objective, according to an embodiment of the present disclosure, there is provided substrate processing equipment, including: a load port where a container containing a substrate is placed; an index module configured to withdraw the substrate from the container and store the substrate in a carrier, and a batch-type liquid processing apparatus configured to perform processing on the substrate stored in the carrier. The batch-type liquid processing apparatus may include: a first cleaning tank configured to store a first processing liquid; a second cleaning tank configured to store a second processing liquid; and a substrate transferring apparatus configured to transfer a substrate immersed in the first cleaning tank to the second cleaning tank. The substrate transferring apparatus may include: a transfer rail extended on a ceiling of the first cleaning tank in which the first processing liquid is stored and the second cleaning tank in which the second processing liquid is stored; a crane moving along the transfer rail; and a vessel configured to be moved vertically by the crane, wherein the vessel comprises a first sub vessel and a second sub vessel that combine with each other to form a space for accommodating the substrate immersed in the first processing liquid.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 shows a layout of substrate processing equipment to which the present disclosure can be applied;

FIG. 2 shows a batch-type liquid processing apparatus in substrate processing equipment according to the present disclosure; and

FIGS. 3 to 14 are views showing the process of transferring a substrate by a substrate transferring apparatus according to the present disclosure.

### DETAILED DESCRIPTION OF THE INVENTION

Hereinafter, specific embodiments of the present disclosure will be described in detail with reference to the accompanying drawings.

In addition, in describing the present disclosure, when it is determined that a detailed description of a related known structure or function may obscure the gist of the present disclosure, the detailed description will be omitted.

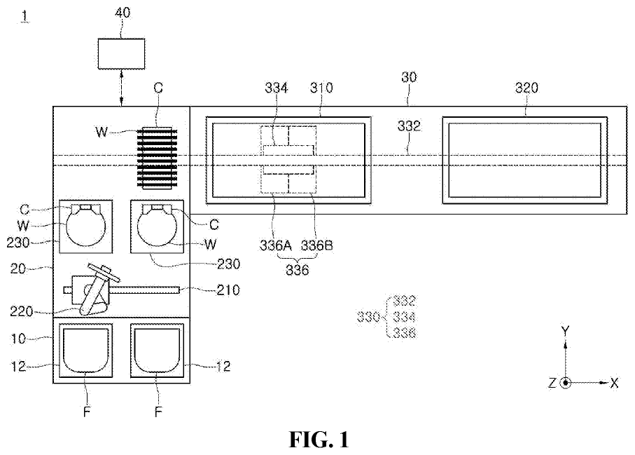

FIG. 1 shows a layout of substrate processing equipment 1 to which the present disclosure can be applied. The substrate processing equipment 1 may be equipment for removing particles remaining on the substrate. The substrate processing equipment 1 may be referred to as cleaning equipment or wet etching equipment.

Referring to FIG. 1, the substrate processing equipment 1 includes: a load port 10 in which a container F containing one or more substrates W is seated; an index module 20 for withdrawing the substrates W from the container F and storing the substrates W in a carrier C; and a batch-type liquid processing apparatus 30 that performs processing on the substrates W stored in the carrier C. In addition, the substrate processing equipment 1 may include a controller 40 to control the operation of each part. The controller 40 may consist of one or more processing circuits.

The load port 10 includes a shelf 12 that accommodates the container F containing a substrate W. The container F may be placed on the shelf 12 of the load port 10 by a transfer apparatus or an operator. A plurality of (e.g., 25) substrates W may be stored in the container F. The container F may be referred to as a cassette, a pod (POD), or a front opening unified pod (FOUP). A container F containing substrates W requiring liquid processing may be located on the shelf 12 of the load port 10, substrates W on which the liquid processing process has been completed may be stored in a container F, and the container F containing the substrates W on which the liquid processing process has been completed may be transferred for the next process.

The index module 20 may be coupled to the load port 10 to withdraw a substrate W from the container F, store the substrate W in the carrier C, withdraw the substrate W on which liquid processing has been completed from the carrier C, and store the substrate W in the container F. The index module 20 includes: an index rail 210 extending along the longitudinal direction (X direction) of the load port 10; an index robot 220 that transfers the substrate W while moving along the index rail 210; and a rotation drive part 230 that changes the posture of the carrier C in which the substrate W is stored. The index robot 220 may carry out the substrate W from the container F seated on the shelf 12 of the load port 10 and store the substrate W in the carrier C. The index robot 220 may include a drive part for moving along the index rail 210, an arm for handling the substrate W, and a hand.

The carrier C has slots into which the substrate W may be inserted. The carrier C accommodates substrates W while standing along the vertical direction (Z direction), and when the carrier C is filled with substrates W, the carrier C is moved in the horizontal direction (Y direction) by the rotation drive part 230. The carrier C may accommodate a plurality of (e.g., 50) substrates W. The carrier C lying down while accommodating substrates W is transferred to the liquid processing apparatus 30 by a substrate transferring apparatus 330.

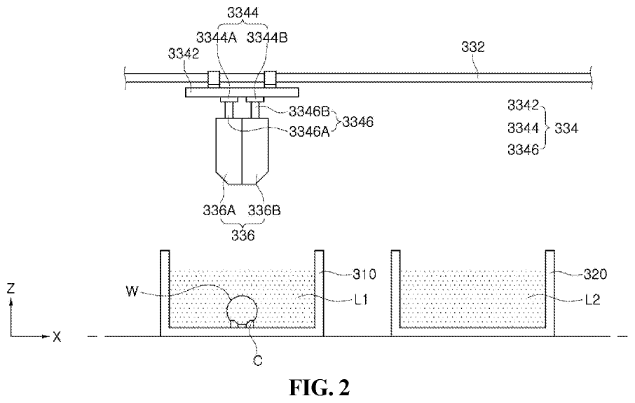

FIG. 2 shows a batch-type liquid processing apparatus 30 in the substrate processing equipment 1 according to the present disclosure. The liquid processing apparatus 30 is coupled to one side of the index module 20 and may perform liquid processing (cleaning, wet etching) on the substrate W. The liquid processing apparatus 30 may include a plurality of cleaning tanks for batch-type cleaning. The liquid processing apparatus 30 includes: a first cleaning tank 310 storing first processing liquid L1; a second cleaning tank 320 storing second processing liquid L2; and the substrate transferring apparatus 330.

According to the present disclosure, the first processing liquid L1 stored in the first cleaning tank 310 is phosphoric acid (H3PO4) that can chemically react with particles remaining on the substrate W, and the second processing liquid L2 stored in the second cleaning tank 320 is DIW (de-ionized water) for rinsing the substrate W.

The first cleaning tank 310 and the second cleaning tank 320 may be arranged along the horizontal direction (X direction). The substrate transferring apparatus 330 may transfer the substrate W along the horizontal direction (X direction). The substrate transferring apparatus 330 includes: a rail 332 extended on the ceiling of the first cleaning tank 310 where the first processing liquid L1 is stored and the second cleaning tank 320 where the second processing liquid L2 is stored; a crane 334 moving along the rail 332; and a vessel 336 configured to move vertically by the crane 334. The vessel 336 includes a first sub vessel 336A and a second sub vessel 336B combined with each other to form a space for accommodating a plurality of substrates W immersed in the first processing liquid L1.

The rail 332 is provided on the ceiling side and extends along the horizontal direction (X direction) where the first cleaning tank 310 and the second cleaning tank 320 are arranged. The rail 332 provides a path along which the crane 334 can move. The rail 332 may be arranged along the position where the carrier C is seated in the liquid processing apparatus 30 and the index module 20.

The crane 334 is configured to move along the rail 332. By moving the crane 334, the vessel 336 moves along the horizontal direction (X direction), and the vessel 336 may be raised or lowered by the crane 334.

The crane 334 includes: a movable body 3342 moving horizontally along the rail 332; a slide drive part 3344 having a first slide drive part 3344A and a second slide drive part 3344B, which are provided on the movable body 3342 and move closer to or farther away from each other, and a lifting belt 3346 having a first lifting belt 3346A and a second lifting belt 3346B respectively provided on the first slide drive part 3344A and the second slide drive part 3344B to raise or lower the first sub vessel 336A and the second sub vessel 336B.

The movable body 3342 may be moved by wheels or by a linear motor that moves along the rail 332 in a non-contact manner. The slide drive part 3344 may be coupled to the lower part of the movable body 3342. The first slide drive part 3344A and the second slide drive part 3344B may move closer to or farther away from each other. The first slide drive part 3344A and the second slide drive part 3344B may move in the horizontal direction (X direction) by a horizontal drive belt or linear motor. The first sub vessel 336A and the second sub vessel 336B may be coupled to or separated from each other by driving the first slide drive part 3344A and the second slide drive part 3344B. The first lifting belt 3346A and the second lifting belt 3346B are respectively coupled to the first sub vessel 336A and the second sub vessel 336B to raise or lower the first sub vessel 336A and the second sub vessel 336B. The first lifting belt 3346A may be provided on the first slide drive part 3344A while the second lifting belt 3346B may be provided on the second slide drive part 3344B. The first lifting belt 3346A and the second lifting belt 3346B may be configured to be wound or unwound by pulleys provided in the first slide drive part 3344A and the second slide drive part 3344B.

The first sub vessel 336A and the second sub vessel 336B may have a barrel shape with the center cut out. The first sub vessel 336A and the second sub vessel 336B may have a barrel shape with the center and top open. The first sub vessel 336A and the second sub vessel 336B may have symmetrical shapes. A sealing member to maintain airtightness may be provided on the center surface where the first sub vessel 336A and the second sub vessel 336B are joined.

The first sub vessel 336A and the second sub vessel 336B may be coupled to each other through horizontal movement. The first sub vessel 336A and the second sub vessel 336B may be coupled to or separated from each other by moving by the first slide drive part 3344A and the second slide drive part 3344B.

According to the present disclosure, in the first cleaning tank 310, by combining the first sub vessel 336A and the second sub vessel 336B, the substrates W are transferred to the second cleaning tank 320 while being immersed in the first processing liquid L1. At this time, since the substrates W are continuously immersed in the first processing liquid L1, pattern collapse that occurs when the substrate W leaves the first processing liquid L1 may be prevented.

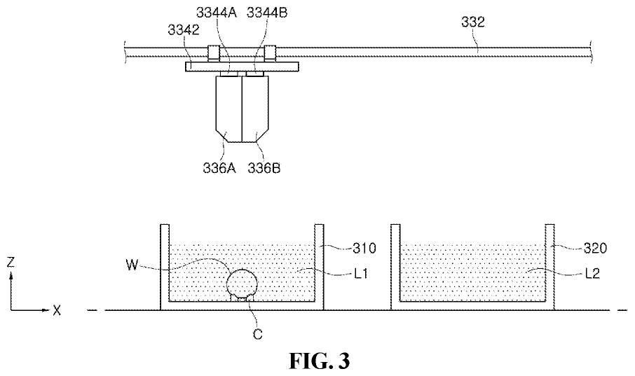

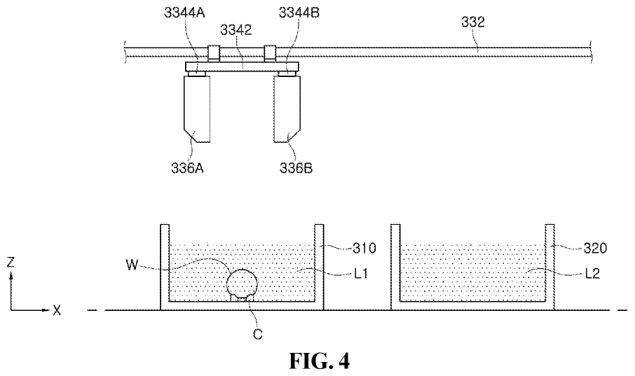

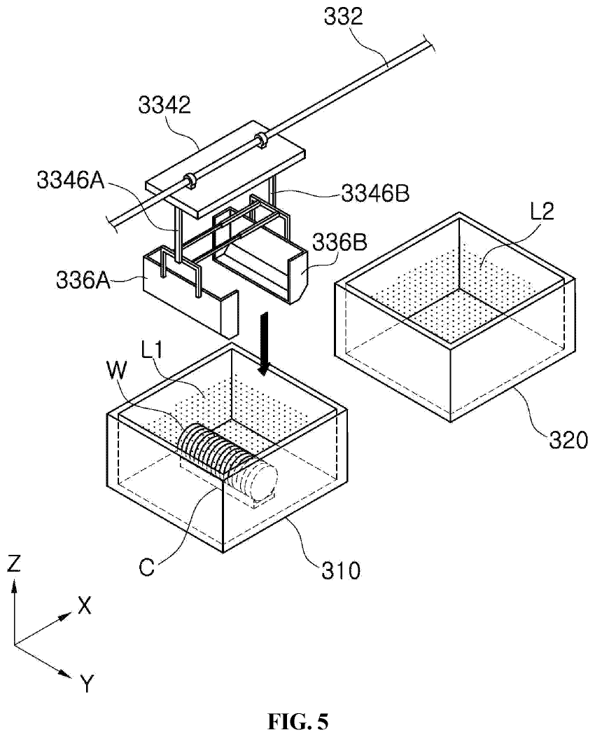

FIGS. 3 to 14 are views showing the process of transferring a substrate W by the substrate transferring apparatus 330 according to the present disclosure. Referring to FIG. 3, a plurality of substrates W are located in the first cleaning tank 310 filled with the first processing liquid L1. In this case, the plurality of substrates W are processed while stored in the carrier C. The first treatment liquid L1 may correspond to a phosphoric acid (H3PO4) cleaning solution and may remove foreign substances remaining on the substrates W through a chemical reaction. When processing of a substrate W is completed in the first cleaning tank 310, the substrate transferring apparatus 330 transfers the substrate W from the first cleaning tank 310 to the second cleaning tank 320. Referring to FIGS. 4 and 5, the first sub vessel 336A and the second sub vessel 336B are located above the first cleaning tank 310 in an open state. The first sub vessel 336A and the second sub vessel 336B may be spaced apart from each other by the opening of the first slide drive part 3344A and the second slide drive part 3344B.

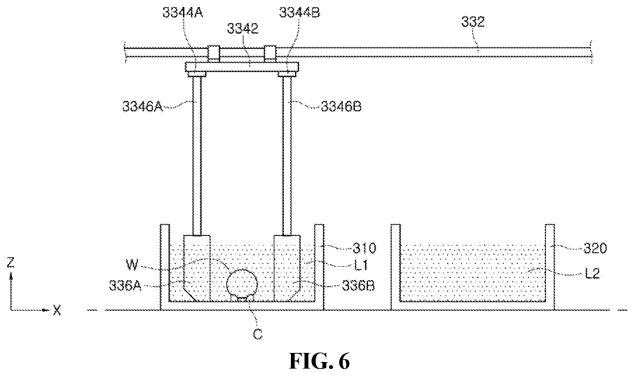

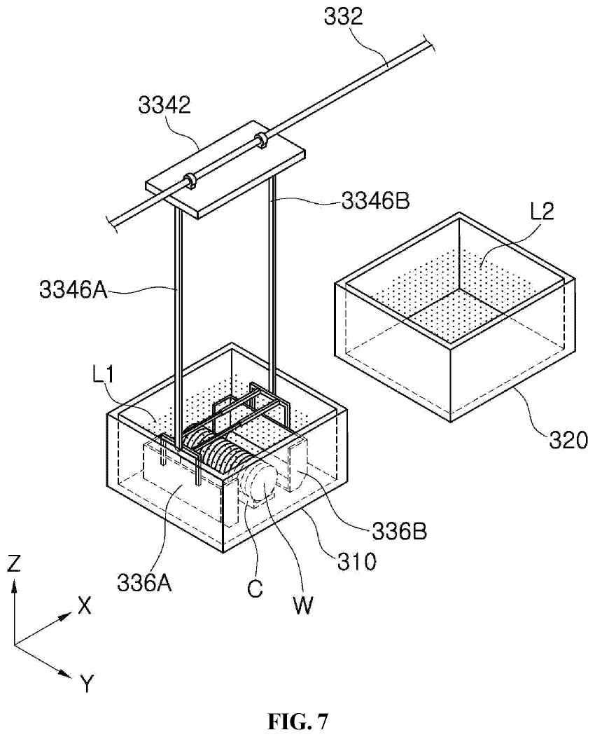

When the position of the movable body 3342 and the position of the substrate W are aligned, the first sub vessel 336A and the second sub vessel 336B are lowered in an open state. Referring to FIGS. 6 and 7, the first sub vessel 336A and the second sub vessel 336B are located on opposite sides of the substrate W, respectively. The first sub vessel 336A and the second sub vessel 336B may be lowered by the first lifting belt 3346A and the second lifting belt 3346B. That is, the vessel 336 is lowered into the first cleaning tank 310 in a state of being separated into the first sub vessel 336A and the second sub vessel 336B so as to be located on opposite sides of the substrate W.

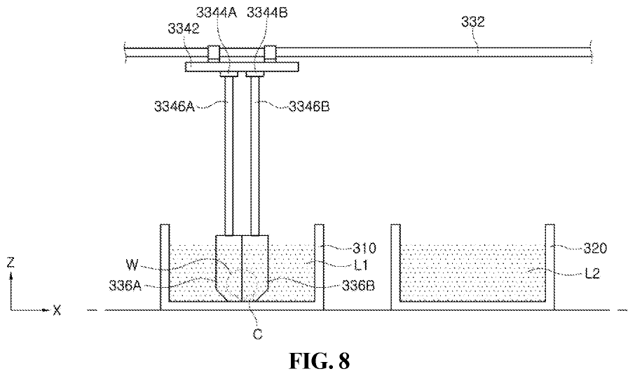

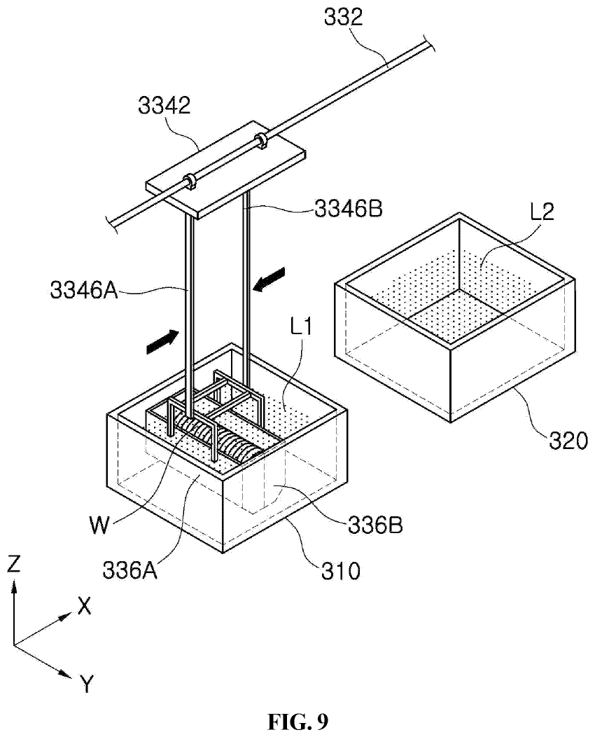

Thereafter, as shown in FIGS. 8 and 9, the first sub vessel 336A and the second sub vessel 336B are coupled to each other, so that the substrates W are accommodated in the internal space of the vessel 336 while being immersed in the first processing liquid L1. The first sub vessel 336A and the second sub vessel 336B may be contacted and coupled to each other by moving the first slide drive part 3344A and the second slide drive part 3344B. A receiving space is formed inside the vessel 336 by combining the first sub vessel 336A and the second sub vessel 336B, and the substrate W and the first processing liquid L1 are accommodated in the receiving space. That is, the first sub vessel 336A and the second sub vessel 336B are coupled to each other, so that the substrate W immersed in the first processing liquid L1 is accommodated in the vessel 336. Because some of the first processing liquid L1 stored in the first cleaning tank 310 is transferred by the vessel 336, the first cleaning tank 310 may be filled with the first processing liquid L1 periodically or according to the water level so that the amount of the first processing liquid L1 in the first cleaning tank 310 is maintained.

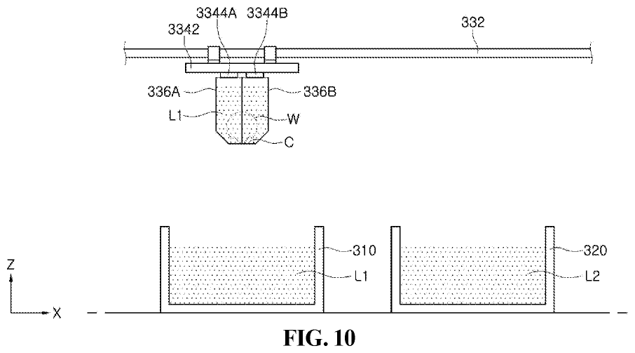

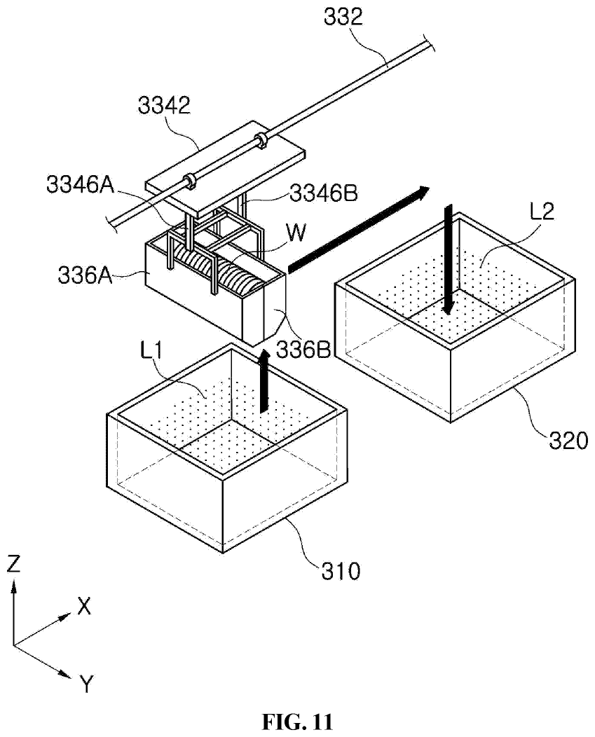

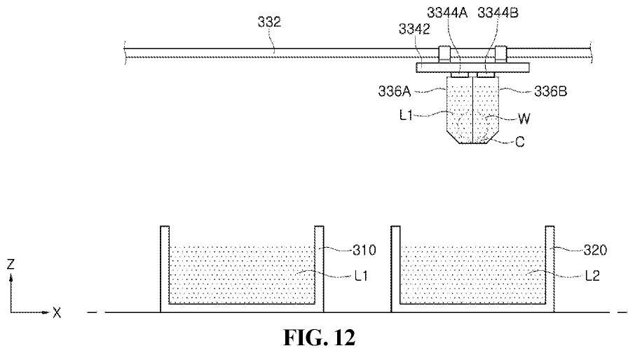

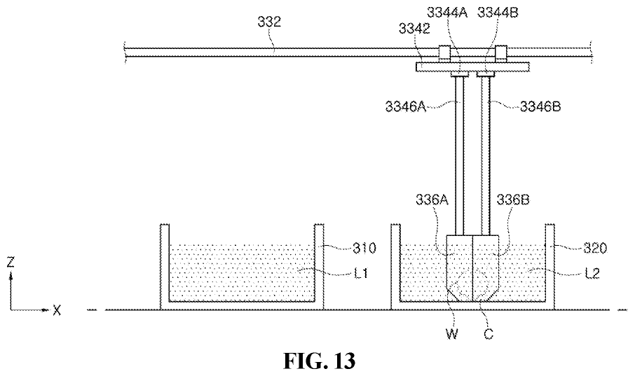

When the substrate W immersed in the first processing liquid L1 is accommodated in the vessel 336, the vessel 336 in which the first sub vessel 336A and the second sub vessel 336B are combined rises as shown in FIGS. 10 and 11. When the vessel 336 rises to a certain height, the movable body 3342 moves toward a position above the second cleaning tank 320 as shown in FIG. 12. Thereafter, as shown in FIG. 13, the vessel 336 in which the first sub vessel 336A and the second sub vessel 336B are combined descends to be located inside the second cleaning tank 320. In the process of moving the vessel 336 from the first cleaning tank 310 to the second cleaning tank 320, a portion of the first processing liquid L1 may fall on the outside of the first cleaning tank 310 or the second cleaning tank 320. A port through which the first processing liquid L1 can be discharged may be formed on the bottom of the liquid processing apparatus 30.

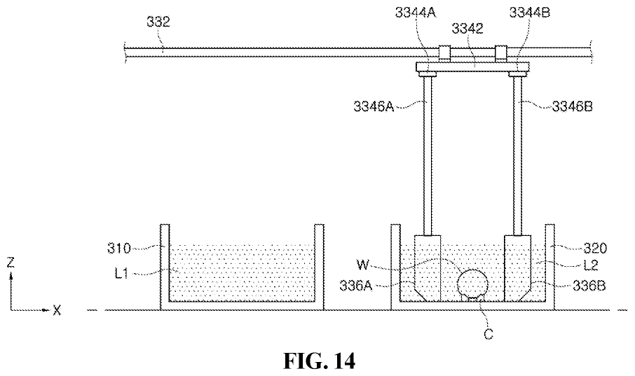

As shown in FIG. 14, as the first sub vessel 336A and the second sub vessel 336B are separated from each other, the substrate W may be immersed in the second processing liquid L2. The substrate W may be processed with the second processing liquid L2 in the second cleaning tank 320. The second processing liquid L2 may correspond to DIW, and the first processing liquid L1 remaining on the substrate W may be washed away by DIW. That is, the vessel 336 containing the substrate W immersed in the first processing liquid L1 moves to the second cleaning tank 320, and in the second cleaning tank 320, the first sub vessel 336A and the second sub vessel 336B are separated from each other, so that the substrate W is located in the second cleaning tank 320.

At this time, mixing of a portion of the first processing liquid L1 and the second processing liquid L2 occurs, and when the processing of the substrate W is completed, the second processing liquid L2 mixed with the first processing liquid L1 is discharged to the outside, and the second cleaning tank 320 is refilled with the second processing liquid L2. When processing of the substrate W is completed in the second cleaning tank 320, the substrate W may be transferred to another location by the substrate transferring apparatus 330. For example, the substrate W may be transferred back to the index module 20 and taken out to the outside. Alternatively, the substrate W may be transferred back to another processing chamber for further processing.

A cleaning process is performed on the substrate W by means of the above-described substrate transferring apparatus 330, and the liquid processing apparatus 30 and the substrate processing equipment 1 including the same. By transferring the substrate W using the vessel 336 consisting of the first sub vessel 336A and the second sub vessel 336B that can be separated and combined with each other, the immersion state of the substrate W may be maintained, and thus pattern leaning phenomenon that occurs when the substrate W is taken out from the processing liquid may be prevented.

The substrate transferring apparatus 330, and the liquid processing apparatus 30 and the substrate processing equipment 1 including the same according to an embodiment of the present disclosure have been described above as specific embodiments, but this is only an example, and the present disclosure is not limited thereto, and should be construed to have the widest scope following the basic idea disclosed herein. A person skilled in the art may combine and substitute the disclosed embodiments to implement embodiments not specified, but this also does not deviate from the scope of the present disclosure. In addition, a person skilled in the art can easily change or modify the disclosed embodiments based on the present specification, and it should be clear that such changes or modifications also fall within the scope of the present disclosure.

What is claimed is:

1. A substrate transferring apparatus that transfers substrates between cleaning tanks in a batch-type liquid processing apparatus, the substrate transferring apparatus comprising:
a rail extended on a ceiling of a first cleaning tank in which a first processing liquid is stored and a second cleaning tank in which a second processing liquid is stored;
a crane moving along the rail; and
a vessel configured to be moved vertically by the crane,
wherein the vessel comprises a first sub vessel and a second sub vessel that combine with each other to form a space for accommodating a substrate immersed in the first processing liquid.

2. The substrate transferring apparatus of claim 1, wherein the first sub vessel and the second sub vessel have a barrel shape with a center cut out.

3. The substrate transferring apparatus of claim 1, wherein the first sub vessel and the second sub vessel are coupled to each other through horizontal movement.

4. The substrate transferring apparatus of claim 1, wherein the crane comprises:
a movable body configured to move horizontally along the rail;
a slide drive part having a first slide drive part and a second slide drive part, which are provided on the movable body and move closer to or farther away from each other; and
a lifting belt having a first lifting belt and a second lifting belt respectively provided on the first slide drive part and the second slide drive part to raise or lower the first sub vessel and the second sub vessel.

5. The substrate transferring apparatus of claim 1, wherein the vessel is lowered into the first cleaning tank in a state of being separated into the first sub vessel and the second sub vessel so as to be located on opposite sides of the substrate, and
as the first sub vessel and the second sub vessel are coupled to each other, the substrate immersed in the first processing liquid is accommodated in the vessel.

6. The substrate transferring apparatus of claim 5, wherein the vessel containing the substrate immersed in the first processing liquid moves to the second cleaning tank, and as the first sub vessel and the second sub vessel are separated from each other in the second cleaning tank, the substrate is located in the second cleaning tank.

7. The substrate transferring apparatus of claim 1, wherein the first processing liquid is phosphoric acid (H3PO4), and the second processing liquid is de-ionized water (DIW).

8. A batch-type liquid processing apparatus, comprising:
a first cleaning tank configured to store a first processing liquid;
a second cleaning tank configured to store a second processing liquid; and
a substrate transferring apparatus configured to transfer a substrate to the first cleaning tank and the second cleaning tank,
wherein the substrate transferring apparatus comprises:
a transfer rail extended on a ceiling of the first cleaning tank in which the first processing liquid is stored and the second cleaning tank in which the second processing liquid is stored;
a crane moving along the transfer rail; and
a vessel configured to be moved vertically by the crane,
wherein the vessel comprises a first sub vessel and a second sub vessel that combine with each other to form a space for accommodating the substrate immersed in the first processing liquid.

9. The batch-type liquid processing apparatus of claim 8, wherein the first sub vessel and the second sub vessel have a barrel shape with a center cut out.

10. The batch-type liquid processing apparatus of claim 8, wherein the first sub vessel and the second sub vessel are coupled to each other through horizontal movement.

11. The batch-type liquid processing apparatus of claim 8, wherein the crane comprises:
a movable body configured to move horizontally along the transfer rail;
a slide drive part having a first slide drive part and a second slide drive part, which are provided on the movable body and move closer to or farther away from each other; and
a lifting belt having a first lifting belt and a second lifting belt respectively provided on the first slide drive part and the second slide drive part to raise or lower the first sub vessel and the second sub vessel.

12. The batch-type liquid processing apparatus of claim 8, wherein the vessel is lowered into the first cleaning tank in a state of being separated into the first sub vessel and the second sub vessel so as to be located on opposite sides of the substrate, and
as the first sub vessel and the second sub vessel are coupled to each other, the substrate immersed in the first processing liquid is accommodated in the vessel.

13. The batch-type liquid processing apparatus of claim 12, wherein the vessel containing the substrate immersed in the first processing liquid moves to the second cleaning tank, and as the first sub vessel and the second sub vessel are separated from each other in the second cleaning tank, the substrate is located in the second cleaning tank.

14. The batch-type liquid processing apparatus of claim 8, wherein the first processing liquid is phosphoric acid (H3PO4), and the second processing liquid is de-ionized water (DIW).

15. Substrate processing equipment, comprising:
a load port where a container containing a substrate is placed;
an index module configured to withdraw the substrate from the container and store the substrate in a carrier, and
a batch-type liquid processing apparatus configured to perform processing on the substrate stored in the carrier,
wherein the batch-type liquid processing apparatus comprises:
a first cleaning tank configured to store a first processing liquid;
a second cleaning tank configured to store a second processing liquid; and
a substrate transferring apparatus configured to transfer a substrate immersed in the first cleaning tank to the second cleaning tank,
wherein the substrate transferring apparatus comprises:
a transfer rail extended on a ceiling of the first cleaning tank in which the first processing liquid is stored and the second cleaning tank in which the second processing liquid is stored;
a crane moving along the transfer rail; and
a vessel configured to be moved vertically by the crane,
wherein the vessel comprises a first sub vessel and a second sub vessel that combine with each other to form a space for accommodating the substrate immersed in the first processing liquid.

16. The substrate processing equipment of claim 15, wherein the first sub vessel and the second sub vessel have a barrel shape with a center cut out.

17. The substrate processing equipment of claim 15, wherein the first sub vessel and the second sub vessel are coupled to each other through horizontal movement.

18. The substrate processing equipment of claim 15, wherein the crane comprises:
a movable body configured to move horizontally along the transfer rail;
a slide drive part having a first slide drive part and a second slide drive part, which are provided on the movable body and move closer to or farther away from each other; and
a lifting belt having a first lifting belt and a second lifting belt respectively provided on the first slide drive part and the second slide drive part to raise or lower the first sub vessel and the second sub vessel.

19. The substrate processing equipment of claim 15, wherein the vessel is lowered into the first cleaning tank in a state of being separated into the first sub vessel and the second sub vessel so as to be located on opposite sides of the substrate, and
as the first sub vessel and the second sub vessel are coupled to each other, the substrate immersed in the first processing liquid is accommodated in the vessel.

20. The substrate processing equipment of claim 19, wherein the vessel containing the substrate immersed in the first processing liquid moves to the second cleaning tank, and as the first sub vessel and the second sub vessel are separated from each other in the second cleaning tank, the substrate is located in the second cleaning tank.
